(19) United States
(12) Patent Application Publication
(10) Pub. No.: US 2025/0023003 A1
(43) Pub. Date: Jan. 16, 2025

(54) Display Device

(71) Applicant: LG Display Co., Ltd., Seoul (KR)

(72) Inventors: Hye Sun Jung, Paju-si (KR); Jae Kwang Lee, Paju-si (KR); Tae Yoon Kim, Paju-si (KR); Bung Goo Kim, Paju-si (KR); Hyoung Ho Ahn, Paju-si (KR); Hee Won Lee, Paju-si (KR); Jun Young Jo, Paju-si (KR); Pyung Ho Choi, Paju-si (KR)

(21) Appl. No.: 18/763,630

(22) Filed: Jul. 3, 2024

(30) Foreign Application Priority Data
Jul. 12, 2023 (KR) 10-2023-0090571

(51) Int. Cl. H01L 33/62; H01L 25/16; H01L 27/12; H01L 33/58

(52) U.S. Cl. CPC H01L 33/62; H01L 25/167; H01L 27/124; H01L 33/58

(57) ABSTRACT

A display device includes a plurality of first electrodes and a contact electrode on a substrate; a plurality of light-emitting elements on the plurality of first electrodes; a first optical layer between the plurality of light-emitting elements; and a second electrode on the plurality of light-emitting elements, the second electrode including a first region that is on the plurality of light-emitting elements and a second region that extends past an end the first optical layer and is in contact with the contact electrode.

### CROSS-REFERENCE TO RELATED APPLICATION

This application claims priority to and the benefit of Republic of Korea Patent Application No. 10-2023-0090571 filed on Jul. 12, 2023 in the Republic of Korea, which is hereby incorporated by reference in its entirety.

### TECHNICAL FIELD

The present disclosure relates to a display device, and particularly to, for example, without limitation, a display device using an inorganic light-emitting diode as the light-emitting element.

### DISCUSSION OF RELATED ART

An electroluminescence display device includes an organic light-emitting display device in which an organic light-emitting diode (OLED) is disposed and an inorganic light-emitting display device (hereinafter, referred to as “an LED display device”) in which an inorganic light-emitting diode (hereinafter, referred to as “an LED”) is disposed.

The electroluminescence display device displays images using self-luminous elements, and thus does not require a separate light source, for example, a backlight unit, and can be thin and implemented in various forms.

In the organic light-emitting display device, since an oxidation phenomenon between an organic light-emitting layer and an electrode can occur due to penetration of moisture and oxygen, a design for preventing or reducing the penetration of oxygen and moisture is required.

Recently, as an example of the inorganic light-emitting display device, a micro-LED display device in which micro LEDs are disposed in pixels has been attracting attention as a next-generation display device. The micro-LED may be an inorganic LED with a size of 100 μm or less. Micro LEDs are manufactured through a separate semiconductor process and transferred to pixel positions on a display panel substrate of the display device, and thus can be respectively disposed in sub-pixels for each color.

### SUMMARY

In the related art, each micro-LED may be connected to an anode electrode and a cathode electrode to receive power. However, it is newly recognized by inventors of the present disclosure that a step is generated in a process in which the cathode electrode is connected to a low potential voltage and stress is concentrated in a portion where the step is generated, and thus cracks occur.

Therefore, the inventors of the present disclosure recognized the problems mentioned above and other limitations associated with the related art, and conducted various experiments to implement a display panel capable of preventing or reducing cracks from occurring in a cathode electrode and a display device including the same.

Additional features and aspects of the disclosure are set forth in part in the description that follows and in part will become apparent from the description or may be learned by practice of the inventive concepts provided herein. Other features and aspects of the inventive concepts may be realized and attained by the structures pointed out in the present disclosure, or derivable therefrom, and the claims hereof as well as the appended drawings.

To achieve these and other aspects of the inventive concepts, as embodied and broadly described herein, a display device includes: a substrate; a plurality of first electrodes on the substrate; a contact electrode on the substrate; a plurality of light-emitting elements on the plurality of first electrodes; a first optical layer between the plurality of light-emitting elements; and a second electrode on the plurality of light-emitting elements, the second electrode including a first region that is on the plurality of light-emitting elements and a second region that extends past an end of the first optical layer and is in contact with the contact electrode.

In one embodiment, a display device comprises: a substrate; a plurality of first electrodes on the substrate; a plurality of light-emitting elements on the plurality of first electrodes; a first optical layer between the plurality of light-emitting elements; a second electrode on the plurality of light-emitting elements, the second electrode including a first region that is on the plurality of light-emitting elements and a second region extends past an end of the first optical layer; and a second optical layer surrounding the first optical layer, the second optical layer on the second region of the second electrode.

In one embodiment, a display device comprises: a substrate; a first electrode on the substrate; a contact electrode on the substrate and including a portion that extends in a first direction, the contact electrode configured to supply a voltage; a light emitting element on the first electrode; a first optical layer surrounding the light emitting element; and a second electrode configured to supply the voltage from the contact electrode to the light emitting element, the second electrode including a first portion that is connected to the light emitting element and extends in the first direction and a second portion extends in the first direction and is in contact with the portion of the contact electrode that extends in the first direction without the first optical layer being over the second portion of the second electrode.

According to example embodiments of the present disclosure, cracks can be prevented or reduced from occurring in a cathode electrode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The above and other aspects, features and advantages of the present disclosure will become more apparent to those of ordinary skill in the art by describing exemplary embodiments thereof in detail with reference to the accompanying drawings, in which:

FIG. 1 is a view illustrating a display device according to an example embodiment of the present specification;

FIG. 2 is an enlarged view illustrating region A in FIG. 1 according to the example embodiment of the present specification;

FIG. 3 is a view illustrating a partial region of a pixel according to the example embodiment of the present specification;

FIG. 4 is a cross-sectional view taken along line I-I′ in FIG. 3 according to the example embodiment of the present specification;

FIG. 5 is a cross-sectional view taken along line II-II′ in FIG. 3 according to the example embodiment of the present specification;

FIG. 6 is a cross-sectional view taken along line III-III′ in FIG. 3 according to the example embodiment of the present specification;

FIG. 7 is a cross-sectional view illustrating an example in which a main light-emitting element and a sub light-emitting element are electrically connected to a pixel driving circuit according to an example embodiment of the present specification;

FIG. 8 is a view illustrating a display device according to another example embodiment of the present specification;

FIG. 9 is a cross-sectional view taken along line IV-IV′ in FIG. 8 according to the example embodiment of the present specification;

FIG. 10 is a view illustrating a state in which stress is concentrated in a second electrode disposed in a through hole;

FIG. 11 is a first modified example of FIG. 8 according to an example embodiment of the present specification;

FIG. 12 is a second modified example of FIG. 8 according to an example embodiment of the present specification; and

FIGS. 13A to 13F are views illustrating a display device manufacturing method according to an example embodiment of the present specification.

Throughout the drawings and the detailed description, unless otherwise described, the same drawing reference numerals should be understood to refer to the same elements, features, and structures. The relative size and depiction of these elements may be exaggerated for clarity, illustration, and convenience

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and features of the present disclosure, and methods of achieving them will become apparent with reference to the following example embodiments, which are described in detail, in conjunction with the accompanying drawings. The present disclosure is not limited to the embodiments to be described below and may be implemented in different forms, the example embodiments are only provided to completely disclose the present disclosure and completely convey the scope of the present disclosure to those skilled in the art, and the present disclosure is defined by scopes of the appended claims. Any implementation described herein as an “example” is not necessarily to be construed as preferred or advantageous over other implementations.

Since the shapes, sizes, proportions, angles, numbers, and the like disclosed in the drawings for describing the example embodiments of the present disclosure are only exemplary, the present disclosure is not limited to the items shown in the drawings. Throughout the specification, the same reference numerals refer to substantially the same components. Further, in describing the present disclosure, when it is determined that a detailed description of related known technology may unnecessarily obscure the gist of the present disclosure, the detailed description thereof will be omitted or briefly provided.

When terms such as ‘providing,’ ‘including,’ ‘having,’ ‘comprising,’ and the like mentioned in the present specification are used, other parts may be added unless terms such as ‘only’ is used. A case in which a component is expressed in a singular form may also be interpreted as a plural form unless explicitly stated otherwise.

In interpreting the components, it should be understood that an error range is included even when there is no separate explicit description.

When a position relationship and an interconnection relationship between two components such as ‘on,’ ‘at an upper portion,’ ‘at a lower portion,’ ‘next to,’‘connect or couple,’ ‘crossing or intersecting,’ or the like are described, one or more other components may be interposed between the components unless a more limiting term, such as ‘immediately’ or ‘directly’ is used.

When a temporal relationship is described as ‘after,’ in succession to,’ ‘and then,’‘before,’ or the like, the temporal relationship may not be continuous on a time axis unless 'a more limiting term, such as “just, ‘immediately’ or ‘directly’ is used.

In describing elements of the present disclosure, the terms like “first,” “second,” “A,” “B,” “(a),” “(b)”, and the like may be used in front of names of components to distinguish the components, but functions, structures, essence, sequence, order, or number of the corresponding components are not limited by these ordinal numbers or component names. For convenience of description, the ordinal numbers in front of the name of the same component may be different between embodiments. Also, when an element or layer is described as being “connected,” “coupled,” or “adhered” to another element or layer, the element or layer can not only be directly connected, or adhered to that other element or layer, but also be indirectly connected, or adhered to that other another element or layer with one or more intervening elements or layers “disposed” between the elements or layers, unless otherwise specified.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various example embodiments of the present disclosure will be described in detail with reference to the accompanying drawings. Further, all the components of each display device according to all embodiments of the present disclosure are operatively coupled and configured.

A display device according to an example embodiment of the present specification includes a display region where an image is displayed or a display panel on which a screen is disposed and a pixel driving circuit which drives the pixels of the display panel. The display region includes a pixel region where the pixels are disposed. The pixel region includes a plurality of light-emitting regions. A light-emitting element is disposed in each of the light-emitting regions. The pixel driving circuit may be built in the display panel.

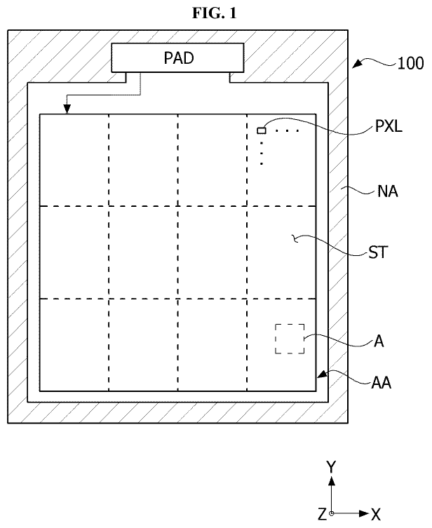

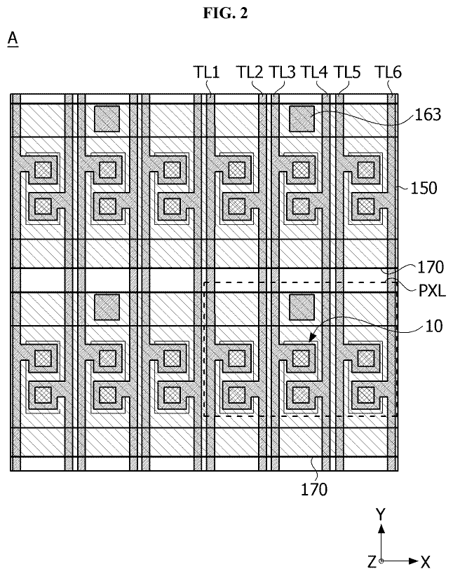

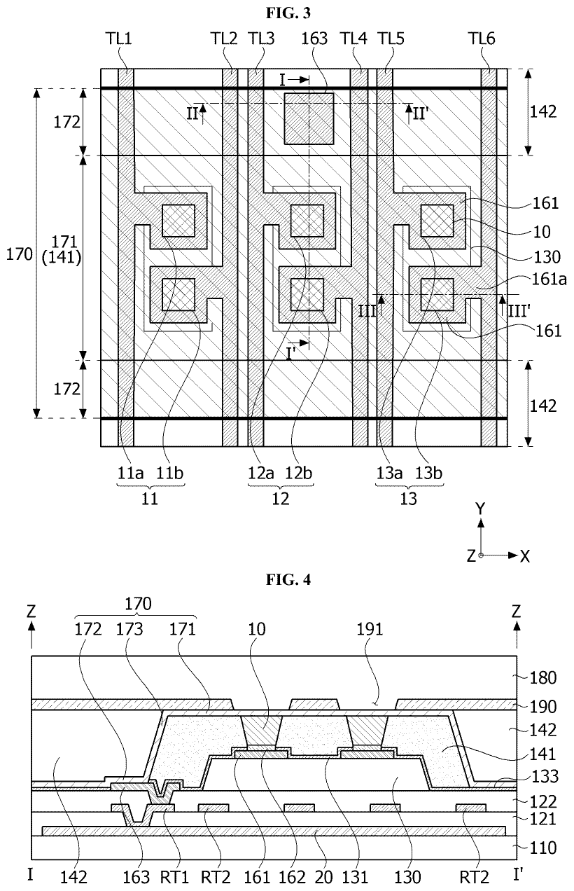

FIG. 1 is a view illustrating the display device according to an example embodiment of the present specification. FIG. 2 is an enlarged view illustrating region A in FIG. 1 according to one embodiment. FIG. 3 is a view illustrating a partial region of a pixel according to one embodiment.

Referring to FIGS. 1 and 2, a display device 100 according to an example embodiment of the present specification includes a display panel where an input image is visually reproduced. The display panel may include a display region AA where an image is displayed and a non-display region NA where the image is not displayed. The non-display region NA may be adjacent to the display region AA, for example, may be disposed around the display region AA. In the non-display region NA, various lines and driving circuits may be mounted, and a pad portion PAD to which an integrated circuit, a printed circuit, and the like are connected may be disposed.

A plurality of light-emitting elements 10 disposed in the display region AA and forming pixels PXL may be micro-sized inorganic light-emitting elements. The inorganic light-emitting elements may be grown on a silicon wafer and then attached to the display panel through a transfer process.

The transfer process of the light-emitting elements 10 may be performed for each previously divided region. In FIG. 1, an example in which the display region AA is divided into nine transfer regions ST is described, but the sizes or number of divided transfer regions are not limited thereto. The transfer process may be performed sequentially or simultaneously on first to ninth transfer regions ST. A blue light-emitting element 10, a green light-emitting element 10, and a red light-emitting element 10 may be sequentially transferred to each transfer region ST.

In the non-display region NA, data driving circuits or gate driving circuits may be disposed, and lines to which control signals for controlling these driving circuits are supplied may be disposed. Here, the control signals may include various timing signals including clock signals, input data enable signals, and synchronization signals and may be received through the pad portion PAD. However, the present disclosure is not limited thereto. For example, at least one of the data driving circuits and the gate driving circuits may be disposed on a lower surface of the display panel and connected to the pixels within the display region AA through the pad portion PAD, thereby the size or area of the non-display region NA may be reduced or minimized. In another example, the gate driving circuits may be integrated within the display region AA.

The pixels PXL may be driven by the pixel driving circuit. The pixel driving circuit may receive a driving voltage, an image signal (for example, data signal), a synchronization signal synchronized with the image signal, and the like and output an anode voltage and a cathode voltage of the light-emitting element 10 to drive a plurality of pixels. The driving voltage may be a high-potential voltage EVDD. The cathode voltage may be a low-potential voltage EVSS applied to the pixels in common. The anode voltage may be a voltage corresponding to a pixel data value of the image signal. The pixel driving circuit may be disposed in the non-display region NA or under the display region AA.

Each pixel PXL may include a plurality of sub-pixels having different colors. For example, each of the plurality of pixels may include a red sub-pixel where the light-emitting element 10 which emits red wavelength light is disposed, a green sub-pixel where the light-emitting element 10 which emits green wavelength light is disposed, and a blue sub-pixel where the light-emitting element 10 which emits blue wavelength light is disposed. The plurality of pixels may further include a white sub-pixel.

Referring to FIGS. 2 and 3, the plurality of pixels PXL may be continuously disposed in a first direction (an X-axis direction) and a second direction (a Y-axis direction). A plurality of sub-pixels of the same color may be disposed in the pixel of the display region AA. For example, each of the plurality of pixels may include a first red sub-pixel where a 1-1 light-emitting element 11a which emits red wavelength light is disposed, a second red sub-pixel where a 1-2 light-emitting element 11b which emits red wavelength light is disposed, a first green sub-pixel where a 2-1 light-emitting element 12a which emits green wavelength light is disposed, a second green sub-pixel where a 2-2 light-emitting element 12b which emits green wavelength light is disposed, a first blue sub-pixel where a 3-1 light-emitting element 13a which emits blue wavelength light is disposed, and a second blue sub-pixel where a 3-2 light-emitting element 13b which emits blue wavelength light is disposed. The 1-1 light-emitting element 11a, the 2-1 light-emitting element 12a, and the 3-1 light-emitting element 13a may be referred to as main light-emitting elements. The 1-2 light-emitting element 11b, the 2-2 light-emitting element 12b, and the 3-2 light-emitting element 13b may be referred to as sub light-emitting elements or redundancy light-emitting elements.

One sub-pixel may include at least one or more light-emitting elements, and thus the luminance of the sub-pixel may be adjusted by increasing the luminance of the other light-emitting elements when one light-emitting element becomes defective. However, the present disclosure is not necessarily limited thereto, and one sub-pixel may include only one light-emitting element.

A plurality of first electrodes 161 may be respectively disposed under the light-emitting elements 10 and may be selectively connected to a plurality of signal lines TL1 to TL6 through a connection portion 161a. The high-potential voltage may be applied to the pixel driving circuit through the signal lines TL1 to TL6. The signal lines TL1 to TL6 and the first electrodes 161 may be formed as an electrode pattern integrated during an electrode patterning process.

For example, a first signal line TL1 may be connected to an anode electrode of the first red sub-pixel, and a second signal line TL2 may be connected to an anode electrode of the second red sub-pixel. A third signal line TL3 may be connected to an anode electrode of the first green sub-pixel, and a fourth signal line TL4 may be connected to an anode electrode of the second green sub-pixel. A fifth signal line TL5 may be connected to an anode electrode of the first blue sub-pixel, and a sixth signal line TL6 may be connected to an anode electrode of the second blue sub-pixel. When one sub-pixel includes only one light-emitting element, the number of signal lines TL may be reduced by half.

A second electrode 170 may be a cathode electrode that is disposed in each row and applies a cathode voltage to the light-emitting elements 10 continuously disposed in the first direction (the X-axis direction). The plurality of second electrodes 170 may be disposed to be spaced apart from each other in the second direction (the Y-axis direction). The plurality of second electrodes 170 may receive the cathode voltage through a contact electrode 163. Each of the plurality of second electrodes 170 may be electrically connected to the contact electrode 163. However, the present disclosure is not necessarily limited thereto, and the second electrode 170 may not be divided into the plurality of second electrodes 170 and may be configured as one electrode layer and function as a common electrode.

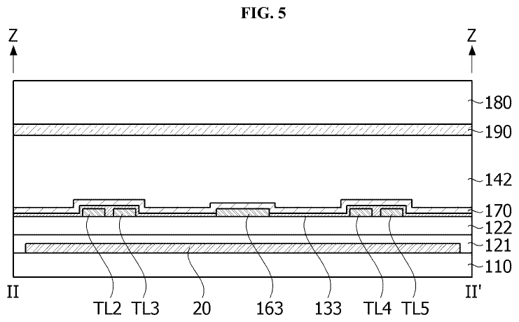

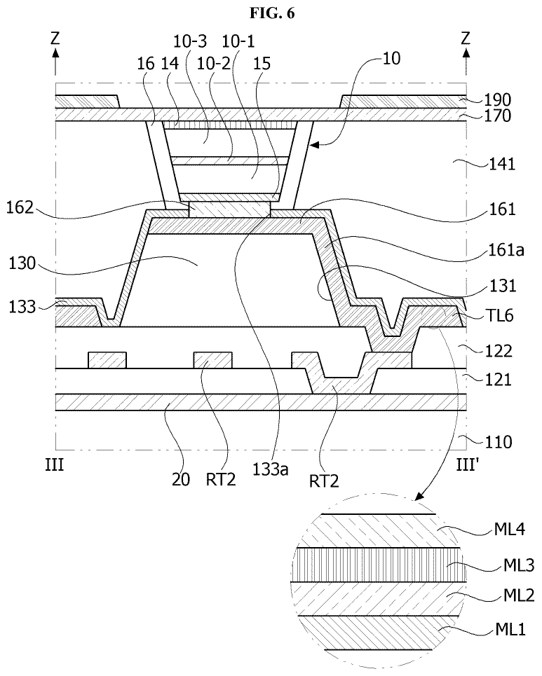

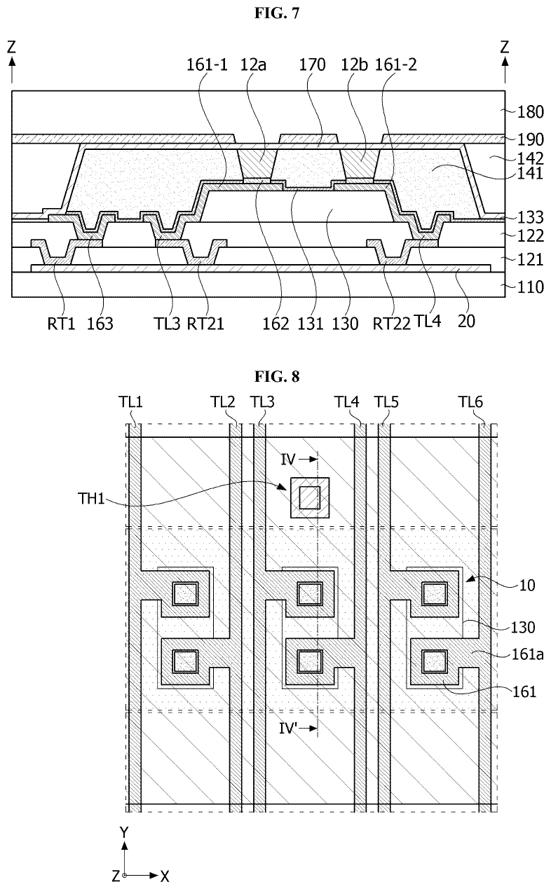

FIG. 4 is a cross-sectional view taken along line I-I′ in FIG. 3 according to one embodiment. FIG. 5 is a cross-sectional view taken along line II-II′ in FIG. 3 according to one embodiment. FIG. 6 is a cross-sectional view taken along line III-III′ in FIG. 3 according to one embodiment. FIG. 7 is a cross-sectional view illustrating an example in which two light-emitting elements are connected to the pixel driving circuit according to one embodiment.

Referring to FIGS. 3 to 5, the display device according to the embodiment includes the plurality of first electrodes 161 and the contact electrode 163 disposed on a substrate 110, the plurality of light-emitting elements 10 disposed on the plurality of first electrodes 161, a first optical layer 141 disposed between the plurality of light-emitting elements 10, and the second electrode 170 disposed on the plurality of light-emitting elements 10.

The substrate 110 may include plastic having flexibility. For example, the substrate 110 may be manufactured as a single-layer or multi-layer substrate made of a material selected from polyimide, polyethylene terephthalate, polyethylene naphthalate, polycarbonate, polyethersulfone, polyarylate, polysulfone, and a cyclic-olefin copolymer, but is not limited thereto. For example, the substrate 110 may be a ceramic substrate or glass substrate.

A pixel driving circuit 20 may be disposed in the display region AA on the substrate 110. The pixel driving circuit 20 may include a plurality of thin film transistors using an amorphous silicon semiconductor, a polycrystalline silicon semiconductor, or an oxide semiconductor as the material of the active layer.

The pixel driving circuit 20 may include at least one driving thin film transistor, at least one switching thin film transistor, and at least one storage capacitor. The pixel driving circuit 20 may be formed on the substrate 110 through a thin film transistor (TFT) manufacturing process when including a plurality of thin film transistors. In the embodiment, the pixel driving circuit 20 may be a concept that collectively refers to a plurality of thin film transistors electrically connected to the light-emitting elements 10.

The pixel driving circuit 20 may be a pixel driver manufactured on a single crystal semiconductor substrate 110 using a metal-oxide-silicon field effect transistor (MOSFET) manufacturing process. The pixel driver may include a plurality of pixel driving circuits to drive a plurality of sub-pixels. When the pixel driving circuit 20 is implemented as the pixel driver, after an adhesive layer is disposed on the substrate 110, the pixel driver may be mounted on the adhesive layer through the transfer process.

A buffer layer 121 which covers the pixel driving circuit 20 may be disposed on the substrate 110. The buffer layer 121 may include an organic insulating material, for example, photosensitive photo acryl or photosensitive polyimide, but is not limited thereto.

The buffer layer 121 may be used by stacking an inorganic insulating material, for example, silicon nitride (SiNₓ), silicon oxide (SiO₂), or the like in a multi-layer manner, or by stacking an organic insulating material and an inorganic insulating material in the multi-layer manner.

An insulating layer 122 may be disposed on the buffer layer 121. The insulating layer 122 may include an organic insulating material, for example, photosensitive photo acryl or photosensitive polyimide, but is not limited thereto. Connection lines RT1 and RT2 may be disposed on the buffer layer 121. The connection lines RT1 and RT2 may be connected to the corresponding signal lines TL1 to TL6 or may be connected to the signal lines TL1 to TL6. The connection lines RT1 and RT2 may include a plurality of line patterns disposed on different layers with one or more insulating layers interposed therebetween. The line patterns disposed on the different layers may be electrically connected through contact holes passing through the insulating layer.

A plurality of bank patterns 130 may be disposed on the insulating layer 122. At least one light-emitting element 10 may be disposed on an upper surface of each bank pattern 130. For example, a first light-emitting element 11 may be disposed on a first bank pattern 130, a second light-emitting element 12 may be disposed on a second bank pattern 130, and a third light-emitting element 13 may be disposed on a third bank pattern 130. As shown in FIG. 4, a first electrode 161 is on an upper surface of a bank pattern 130 such that the first electrode 161 is between the bank pattern 130 and a light-emitting element 10.

The bank pattern 130 may include an organic insulating material, for example, photosensitive photo acryl or photosensitive polyimide, but is not limited thereto. The bank pattern 130 may guide a position where the light-emitting elements 10 will be attached during the transfer process of the light-emitting elements 10. The bank pattern 130 may also be omitted.

A solder pattern 162 may be disposed on the first electrode 161. The solder pattern 162 may include indium (In), tin (Sn), or an alloy thereof, but is not limited thereto. The solder pattern 162 may also be referred to as a conductive connection pattern/layer or a conductive adhesive pattern/layer. However, the present disclosure is not limited thereto, and the solder pattern 162 may be omitted.

Each of the plurality of light-emitting elements 10 may be mounted on the solder pattern 162. One pixel may include light-emitting elements 10 of three colors. The first light-emitting element 11 may be a red light-emitting element, the second light-emitting element 12 may be a green light-emitting element, and the third light-emitting element 13 may be a blue light-emitting element. Two light-emitting elements may be mounted in each sub-pixel.

The first optical layer 141 may cover the plurality of light-emitting elements 10 and the bank pattern 130. Accordingly, the first optical layer 141 may cover a space between the plurality of light-emitting elements 10 and a portion of a space between the plurality of bank patterns 130. The first optical layers 141 may extend in the first direction (X) and may be spaced apart in the second direction (Y) to be separated between pixel rows.

The first optical layer 141 may include an organic insulating material in which light scattering particles, for example, but not limited to, fine metal particles such as titanium dioxide particles, are dispersed. Light emitted from the plurality of light-emitting elements 10 may be scattered by the fine metal particles dispersed in the first optical layer 141 and emitted to the outside.

The second electrode 170 may be disposed on the plurality of light-emitting elements 10. The second electrode 170 may be connected to the plurality of pixels PXL in common. That is, the second electrode 170 may be connected to multiple pixels PXL. The second electrode 170 may be a thin electrode that transmits light. The second electrode 170 may include a transparent electrode material, for example, indium tin oxide (ITO), but is not necessarily limited thereto.

The second electrode 170 may extend in the first direction (the X-axis direction) and may be spaced apart in the second direction (the Y-axis direction). The second electrode 170 may include a first region 171 (e.g., a first portion or first part) disposed on an upper surface of the light-emitting element 10 and an upper surface of the first optical layer 141 at a first height with respect to the substrate 110, a second region 172 (e.g., a second portion or second part) at a second height that is less than the first height with respect to the substrate 110 and is in contact with a portion of the contact electrode 163 and electrically connected to the contact electrode 163, and a third region 173 (e.g., a third portion or third part) which is disposed on a side surface of the first optical layer 141 and connects the first region 171 and the second region 172. In one embodiment, the third region 173 is inclined with respect to the substrate 110. In one embodiment, the first region 171 of the second electrode 170, the second region 172 of the second electrode 170, and the portion of the contact electrode 163 that is in contact with the second region 172 of the second electrode 170 extend in a first direction (e.g., a horizontal direction). As shown in FIG. 4, the second region 172 of the second electrode 170 extends past an end of the third region 173 such that the first optical layer 141 is not over the second region 172 of the second electrode 170.

Each of the plurality of second electrodes 170 may overlap the first optical layer 141 on a plane, and the second region 172 may cover a plane outside the first optical layer 141.

A second optical layer 142 may be an organic insulating material surrounding the first optical layer 141. The second optical layer 142 may be disposed on the insulating layer 122 along with the first optical layer 141. The second optical layer 142 may not include the fine metal particles within the first optical layer 141. The first optical layer 141 and the second optical layer 142 may include the same material (for example, siloxane). For example, the first optical layer 141 may be siloxane including titanium oxide (TiOₓ), and the second optical layer 142 may be siloxane not including titanium oxide (TiOₓ). However, the present disclosure is not necessarily limited thereto, and the first optical layer 141 and the second optical layer 142 may be formed of the same material or may be formed of different materials. That is, the first optical layer 141 includes a first material and the second optical layer 142 includes a second material that is different from the first material.

According to the embodiment, since the second region 172 of the second electrode 170 is connected to the portion of the contact electrode 163 in an overall flat state, excessive stress is not concentrated at a point connected to the contact electrode 163. Accordingly, it is possible to effectively prevent or reduce cracks from occurring in the second electrode 170. That is, a portion of the contact electrode 163 extends in the horizontal direction and a portion of the second region 172 of the second electrode 170 that is in contact with the portion of the contact electrode 163 also extends in the horizontal direction.

The second optical layer 142 may cover the second region 172 and the third region 173 of the second electrode 170 such that the third region 173 is between the second optical layer 142 and the first optical layer 141. The upper surface of the second optical layer 142 and an upper surface of the first region 171 of the second electrode 170 may form the same plane. In other word, the upper surface of the second optical layer 142 and an upper surface of the first region 171 of the second electrode 170 may be located at a same level or height or are aligned. For example, the first optical layer 141 and the second optical layer 142 may function as a planarization layer. Accordingly, since there is no step on a surface where a black matrix 190 is formed, a pattern of the black matrix 190 may be easily formed on the first optical layer 141 and the second optical layer 142. However, the present disclosure is not necessarily limited thereto, and the upper surfaces of the second optical layer 142 and the second electrode 170 may have different heights.

The black matrix 190 may be an organic insulating material to which a black pigment is added. The second electrode 170 may be in contact with the contact electrode 163 under the black matrix 190. A transmission hole 191 through which light emitted from the light-emitting elements 10 is emitted to the outside may be formed between the patterns of the black matrix 190. The black matrix 190 may improve the problem of mixing of light emitted from neighboring light-emitting elements 10 by the first optical layer 141.

A cover layer 180 may be an organic insulating material which covers the black matrix 190 and the second electrode 170. In FIG. 3, the configurations of the black matrix 190 and the cover layer 180 are omitted.

The contact electrode 163 is electrically connected to a first connection line RT1 disposed at a lower portion, and the first connection line RT1 may be connected to the pixel driving circuit 20. Accordingly, the cathode voltage may be applied to the second electrode 170 through the contact electrode 163. The first electrode 161 may be electrically connected to a second connection line RT2. This will be described below.

Referring to FIG. 5, the contact electrode 163 and the signal lines TL1 to TL6 may be disposed on the same plane. The pixel driving circuit 20 may be disposed under the contact electrode 163 and the signal lines TL1 to TL6. When the pixel driving circuit 20 is a pixel driver, a plurality of pixel drivers may be disposed in the display panel.

A passivation layer 133 may expose the contact electrode 163 so that the contact electrode 163 and the second electrode 170 may be electrically connected. Further, the passivation layer 133 may insulate the signal lines TL2 to TL5 and the second electrode 170.

Referring to FIG. 6, the connection portion 161a of the first electrode 161 may extend to one side surface 131 of the bank pattern 130 and may be electrically connected to the connection line RT2 disposed on the insulating layer 122.

The first electrode 161, the connection portion 161a, the signal lines TL, and/or the connection lines RT1 and RT2 may include a single layer or multi-layer metal layer selected from titanium (Ti), molybdenum (Mo), and aluminum (Al). The first electrode 161, the connection portion 161a, the signal lines TL, and/or the connection lines RT1 and RT2 may be formed in a multi-layer structure including a first layer ML1, a second layer ML2, a third layer ML3, and a fourth layer ML4, and more or less layers may be included in the multi-layer structure.

The first layer ML1 and the third layer ML3 may include titanium (Ti) or molybdenum (Mo). The second layer ML2 may include aluminum (Al). The fourth layer ML4 may include a transparent conductive oxide layer such as indium tin oxide (ITO) or indium zinc oxide (IZO) which has excellent adhesion with the solder pattern 162 and is corrosion and acid resistant.

The first layer ML1, the second layer ML2, the third layer ML3, and the fourth layer ML4 may be sequentially deposited and then may be patterned by performing a photolithography process and an etching process.

The passivation layer 133 may be disposed on the first electrode 161 and the signal line TL and include an opening hole 133a which exposes the solder pattern 162.

The light-emitting element 10 may include a first conductivity-type semiconductor layer 10-1, an active layer 10-2 disposed on the first conductivity-type semiconductor layer 10-1, and a second conductivity-type semiconductor layer 10-3 disposed on the active layer 10-2. A first driving electrode 15 may be disposed under the first conductivity-type semiconductor layer 10-1, and a second driving electrode 14 may be disposed on the second conductivity-type semiconductor layer 10-3.

The light-emitting element 10 may be formed on a silicon wafer using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, or the like.

The first conductivity-type semiconductor layer 10-1 may be implemented with a compound semiconductor of group III-V, group II-VI, or the like and may be doped with a first dopant. The first conductivity-type semiconductor layer 10-1 may be formed of any one selected from semiconductor materials having a composition formula of Alₓ₁In_{y1}Ga_{(1-x1-y1)}N(0<=x1<=1, 0<=y1<=1, and 0<=x1+y1<=1), InAlGaN, AlGaAs, GaP, GaAs, GaAsP, and AlGaInP, but is not limited thereto. When the first dopant is an n-type dopant such as Si, Ge, Sn, Se, Te, or the like, the first conductivity-type semiconductor layer 10-1 may be an n-type nitride semiconductor layer. However, when the first dopant is a p-type dopant, the first conductivity-type semiconductor layer 10-1 may be a p-type nitride semiconductor layer.

The active layer 10-2 is a layer in which electrons (or holes) injected through the first conductivity-type semiconductor layer 10-1 and holes (or electrons) injected through the second conductivity-type semiconductor layer 10-3 meet. As the electrons and the holes recombine in the active layer 10-2, the electrons transition to a low energy level, and light having a wavelength corresponding thereto may be generated.

The active layer 10-2 may have one structure among a single well structure, a multiple well structure, a single quantum well structure, a multi quantum well (MQW) structure, a quantum dot structure, and a quantum line structure, but the structure of the active layer 10-2 is not limited thereto. The active layer 10-2 may generate light in the visible light wavelength band. For example, the active layer 10-2 may output light in any one of the blue, green, and red wavelength bands.

The second conductivity-type semiconductor layer 10-3 may be disposed on the active layer 10-2. The second conductivity-type semiconductor layer 10-3 may be implemented with a compound semiconductor of group III-V, group II-VI, or the like, and may be doped with a second dopant. The second conductivity-type semiconductor layer 10-3 may be formed of any one selected from semiconductor materials having a composition formula of Inₓ₂Al_{y2}Ga_{1-x2-y2}N (0<=x2<=1, 0<=y2<=1, and 0<=x2+y2<=1), AlInN, AlGaAs, GaP, GaAs, GaAsP, and AlGaInP, but is not limited thereto. When the second dopant is a p-type dopant such as Mg, Zn, Ca, Sr, Ba, or the like, the second conductivity-type semiconductor layer 10-3 may be a p-type semiconductor layer. However, when the second dopant is an n-type dopant, the second conductivity-type semiconductor layer 10-3 may be an n-type nitride semiconductor layer.

A reflective layer 16 may be disposed on the side surfaces and lower portion of the light-emitting element 10. The reflective layer 16 may have a structure in which a reflective material is dispersed in a resin layer, but is not necessarily limited thereto. For example, the reflective layer 16 may be manufactured as a reflector in various structures. Since light emitted from the active layer 10-2 is reflected upward by the reflective layer 16, light extraction efficiency may increase.

In the embodiment, although a vertical structure in which the driving electrodes 14 and 15 are disposed on and under a light-emitting structure is described, the present disclosure is not limited thereto, and the light-emitting element may have a lateral structure or flip chip structure in addition to the vertical structure. Therefore, the driving electrodes 14 and 15 may also be disposed at a same side of the light-emitting structure when the light-emitting element is implemented with the later structure.

Referring to FIG. 7, a main light-emitting element 12a and a sub light-emitting element 12b of the sub-pixel may be disposed on the bank pattern 130. The second light-emitting element 12 will be described as an example. A 1-1 electrode 161-1 connected to the main light-emitting element 12a extends to one side surface of the bank pattern 130 to be electrically connected to a 2-1 connection line RT21 disposed at a lower portion. A 1-2 electrode 161-2 connected to the sub light-emitting element 12b may extend to the other side surface of the bank pattern 130 to be electrically connected to a 2-2 connection line RT22 disposed at a lower portion.

The pixel driving circuit 20 may apply an anode voltage to the main light-emitting element 12a through the 2-1 connection line RT21, and apply an anode voltage to the sub light-emitting element 12b through the 2-2 connection line RT22. The pixel driving circuit 20 may apply a cathode voltage to the main light-emitting element 12a and the sub light-emitting element 12b through the first connection line RT1 and the second electrode 170.

The pixel driving circuit 20 may control luminance by driving the main light-emitting element 12a without driving the sub light-emitting element 12b, or may also control luminance by simultaneously driving the main light-emitting element 12a and the sub light-emitting element 12b. When the main light-emitting element 12a is darkened, luminance may be adjusted by driving only the sub light-emitting element 12b.

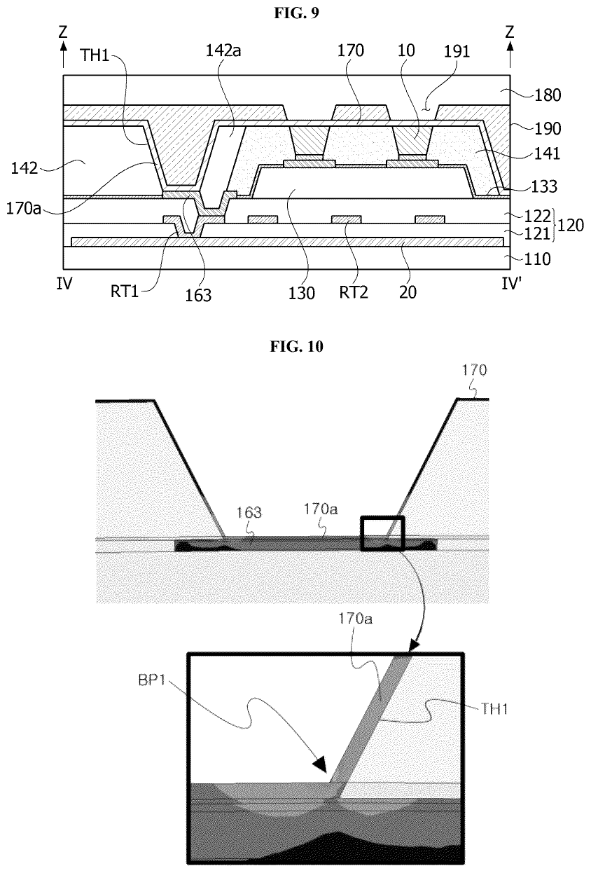

FIG. 8 is a view illustrating a display device according to another embodiment of the present specification. FIG. 9 is a cross-sectional view taken along line IV-IV′ in FIG. 8 according to one embodiment. FIG. 10 is a view illustrating a state in which stress is concentrated in a second electrode disposed in a through hole according to one embodiment.

Referring to FIGS. 8 and 9, a second electrode 170 may be electrically connected to a contact electrode 163 through a contact hole TH1 formed in a second optical layer 142. The second optical layer 142 may include the contact hole TH1 which exposes the contact electrode 163. The second electrode 170 may be inserted into the contact hole TH1 of the second optical layer 142 and come into contact with an upper surface of the contact electrode 163. The contact hole TH1 may be formed in an outer region of a pixel.

Referring to FIG. 10, since a thickness of the second electrode 170 is relatively thin and the contact hole TH1 is formed to be deeper than the thickness of the second electrode 170, a stress concentration area BPl may be generated in a partial region 170a of the second electrode 170 formed on a side surface portion of the contact hole TH1. Accordingly, there is a risk of cracks occurring in the partial region 170a of the second electrode 170 formed around the contact hole TH1.

However, when the second electrode 170 is connected to the contact electrode 163 in a state of evenly extending instead of forming the contact hole TH1 as previously shown in FIG. 4, excessive stress may be prevented or reduced from being applied to the second electrode 170. Accordingly, cracks may be prevented or reduced from occurring in the second electrode.

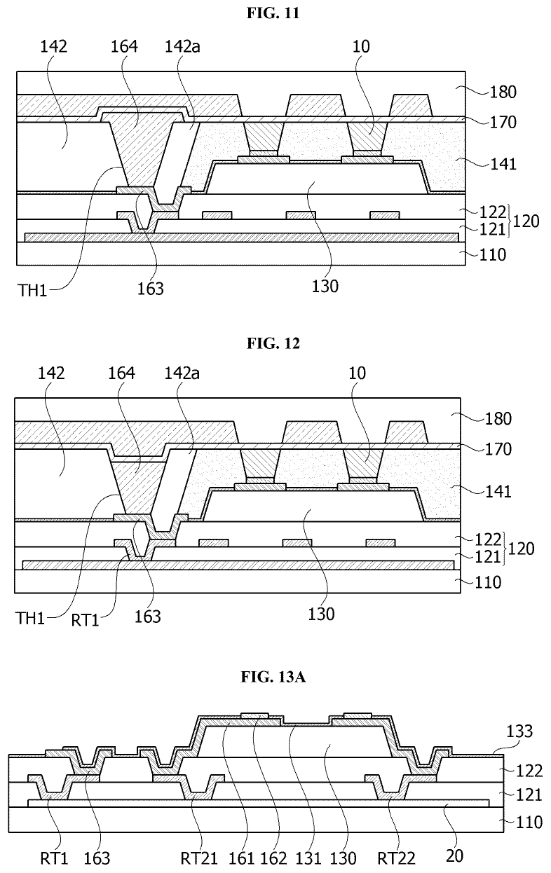

FIG. 11 is a first modified example of FIG. 8 according to one embodiment. FIG. 12 is a second modified example of FIG. 8 according to one embodiment.

Referring to FIG. 11, a separate through electrode 164 may be filled in the contact hole TH1. The through electrode 164 is conductive. The through electrode 164 may include various conductive materials which may be filled in the contact hole TH1. Since the second electrode 170 is disposed on the through electrode 164 and thus is relatively evenly formed, excessive stress may be prevented or reduced from occurring.

Referring to FIG. 12, the through electrode 164 may not completely fill the contact hole TH1 but may partially fill the through hole TH1 to a certain height. According to this structure, a depth to which the second electrode 170 is inserted into the contact hole TH1 may become relatively low. Accordingly, since a step of the second electrode 170 may be reduced, probability of cracks occurring may decrease.

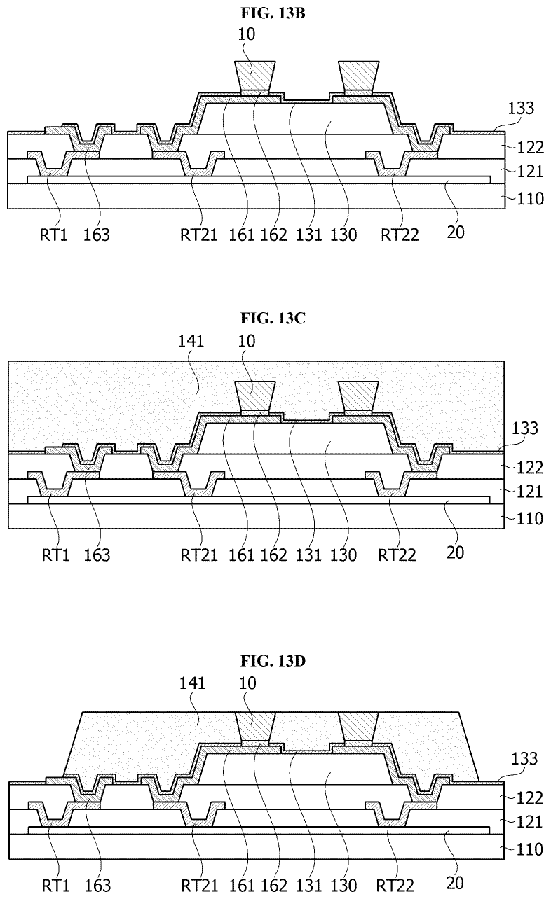

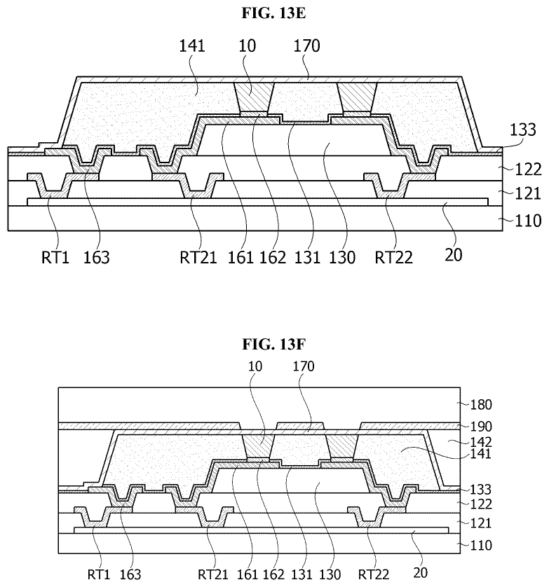

FIGS. 13A to 13F are views illustrating a display device manufacturing method to an example embodiment of the present specification.

Referring to FIG. 13A, a pixel driving circuit 20 may be formed on a substrate 110, and a buffer layer 121 may be formed on the pixel driving circuit 20. The pixel driving circuit 20 may receive a driving voltage, an image signal (a digital signal), a synchronization signal synchronized with the image signal, and the like and output an anode voltage and a cathode voltage of a light-emitting element 10 to drive a plurality of pixels. The pixel driving circuit 20 may be disposed in a non-display region NA or under a display region AA.

Thereafter, connection lines RT1 and RT2 may be formed on the buffer layer 121 and then an insulating layer 122 may be formed. The connection lines RT1 and RT2 may be electrically connected to the pixel driving circuit 20 through the buffer layer 121. In order to drive each pixel, the number of connection lines RT1 and RT2 and the stack number may be variously changed. Accordingly, the stack number of the connection lines RT1 and RT2 and the insulating layer 122 may be two or more layers.

A bank pattern 130 may be formed on the insulating layer 122 to select a position where the light-emitting elements 10 are transferred. The bank pattern 130 may include an organic insulating material, for example, photosensitive photo acryl or photosensitive polyimide, but is not limited thereto. The bank pattern 130 may guide a position where the light-emitting elements 10 will be attached during a transfer process of the light-emitting elements 10. However, the bank pattern 130 may also be omitted.

An electrode material may be applied and then patterned on the insulating layer 122 and the bank pattern 130 to form a plurality of first electrodes 161 and a contact electrode 163. The plurality of first electrodes 161 are regions where the light-emitting elements 10 are disposed, and the contact electrode 163 is a region to which the second electrodes 170 are electrically connected. Thereafter, a passivation layer 133 may be formed in the remaining electrode region excluding the regions where the plurality of first electrodes 161 and the contact electrode 163 are formed.

A solder pattern 162 may be disposed on the first electrode 161. The solder pattern 162 may include indium (In), tin (Sn), or an alloy thereof, but is not limited thereto.

Referring to FIG. 13B, each of the plurality of light-emitting elements 10 may be mounted on the solder pattern 162. One pixel may include light-emitting elements 10 of three colors. A first light-emitting element may be a red light-emitting element, a second light-emitting element may be a green light-emitting element, and a third light-emitting element may be a blue light-emitting element. Two light-emitting elements may be mounted in each sub-pixel.

The transfer method is not particularly limited. For example, the light-emitting elements 10 grown on a semiconductor growth substrate may be primarily transferred to a transfer substrate and then secondarily transferred to a panel substrate, or the light-emitting elements 10 grown on the semiconductor growth substrate may be directly transferred to the panel substrate.

Referring to FIGS. 13C and 13D, a first optical layer 141 may be formed entirely on the substrate 110 and then may be patterned so that upper surfaces of the light-emitting elements 10 and the contact electrode 163 may be exposed. The remaining portion of the first optical layer 141 except for an area sufficient to cover the light-emitting elements 10 and the bank pattern 130 may be removed. Accordingly, the first optical layer 141 may cover a space between the plurality of light-emitting elements 10 and a space between the plurality of bank patterns 130. In this case, the upper surfaces of the light-emitting elements 10 may be exposed at an upper portion of the first optical layer 141.

The first optical layer 141 may include an organic insulating material in which fine metal particles such as titanium dioxide particles are dispersed. Light emitted from the light-emitting elements 10 may be scattered by the fine metal particles dispersed in the first optical layer 141 and emitted.

Referring to FIG. 13E, the second electrode 170 may be disposed on the plurality of light-emitting elements 10. The second electrode 170 may be connected to a plurality of pixels in common. The second electrode 170 may be a thin metal electrode that transmits light. The second electrode 170 may be a transparent electrode material, for example, indium tin oxide (ITO), but is not necessarily limited thereto.

The second electrode 170 may be divided to be disposed in each row through patterning. A plurality of divided second electrodes 170 may be electrically connected to the contact electrode 163.

Referring to FIG. 13F, a second optical layer 142 may be formed to surround the first optical layer 141. In this process, the second optical layer 142 may cover a portion where the second electrode 170 is connected to the contact electrode 163.

The second optical layer 142 may be disposed on the insulating layer 122 along with the first optical layer 141. The first optical layer 141 and the second optical layer 142 may include the same material (for example, siloxane). For example, the first optical layer 141 may be siloxane including titanium oxide (TiOₓ), and the second optical layer 142 may be siloxane not including titanium oxide (TiOₓ).

Thereafter, a black matrix 190 may be formed on the second electrode 170 and the second optical layer 142, and a cover layer 180 may be formed on the black matrix 190.

The display device according to the embodiment of the present specification may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop personal computer (PC), a laptop PC, a netbook computer, a workstation, a navigation, a vehicle display device, a theater display device, a television, a wallpaper apparatus, a signage apparatus, a gaming apparatus, a notebook, a monitor, a camera, a camcorder, a home appliance, and the like. Further, the display device according to one or more embodiments of the present specification may be applied to an organic light-emitting lighting device or inorganic light-emitting lighting device.

The display device according to one or more embodiments of the present specification may be described as follows.

A display device according to one or more embodiments of the present specification includes: a plurality of first electrodes and a contact electrode disposed on a substrate; a plurality of light-emitting elements disposed over the contact electrode; a first optical layer disposed between the plurality of light-emitting elements; and a second electrode disposed on the first optical layer, wherein the plurality of light-emitting elements are electrically connected between the plurality of first electrodes and the second electrode, wherein the second electrode includes a first region disposed on the first optical layer and a second region extending to the outside of the first optical layer and electrically connected to the contact electrode.

The second region of the second electrode may be evenly formed such that the second region of the second electrode is electrically connected to the contact electrode in a flat form

The display device may further include a second optical layer configured to cover the second region of the second electrode.

An upper surface of the second optical layer and an upper surface of the first region of the second electrode may form a same plane.

The first optical layer and the second optical layer may be made of different materials.

The first optical layer may include light scattering particles.

The display device may further include a plurality of bank patterns disposed under the plurality of light-emitting elements.

The display device may further include a plurality of signal lines extending between the plurality of bank patterns and connected to the plurality of first electrodes.

The contact electrode may be disposed between the plurality of signal lines.

The display device may further include a passivation layer disposed on the contact electrode and the plurality of signal lines and exposing the contact electrode so that the contact electrode and the second electrode are electrically connected.

A plurality of second electrodes may be disposed to be spaced apart from each other for each pixel row, and the plurality of second electrodes may be electrically connected to the contact electrode.

The second electrode may include a third region configured to extend toward a side surface of the first optical layer and connect the first region and the second region.

The display device may further include: an insulating layer disposed on the substrate; a plurality of connection lines disposed between the substrate and the insulating layer; and a pixel driving circuit connected to the plurality of connection lines, wherein the plurality of connection lines may be electrically connected to the plurality of first electrodes and the contact electrode respectively.

The plurality of light-emitting elements may be inorganic light-emitting diodes.

The pixel driving circuit may be a pixel driver.

The display device may further include: a second optical layer located between the second region of the second electrode and the contact electrode; and a through electrode at least partially filling a contact hole of the second optical layer to electrically connect the second region of the second electrode to the contact electrode.

The through electrode may completely fill the contact hole.

A display device according to one or more embodiments of the present specification includes: a plurality of light-emitting elements disposed on the substrate and connected to a plurality of first electrodes respectively; a first optical layer disposed between the plurality of light-emitting elements; a second electrode disposed on the first optical layer; and a second optical layer surrounding the first optical layer, wherein the plurality of light-emitting elements are electrically connected between the plurality of first electrodes and the second electrode, wherein the second electrode includes a first region disposed on the first optical layer and a second region extending to the outside of the first optical layer, and the second optical layer is disposed on the second region of the second electrode.

The first optical layer and the second optical layer may be made of different materials.

The first optical layer may include light scattering particles.

The display device may further include a plurality of bank patterns disposed under the plurality of light-emitting elements.

The display device may further include a plurality of signal lines extending between the plurality of bank patterns and connected to the plurality of first electrodes.

The display device may include a contact electrode disposed on the substrate and electrically connected to the second electrode, wherein the contact electrode may be disposed between the plurality of signal lines.

A plurality of second electrodes may be disposed to be spaced apart from each other for each pixel row, and the plurality of second electrodes may be electrically connected to the contact electrode.

The display device may further include: an insulating layer disposed on the substrate; a plurality of connection lines disposed between the substrate and the insulating layer; and a pixel driving circuit connected to the plurality of connection lines, wherein the plurality of connection lines may be electrically connected to the plurality of first electrodes and the contact electrode respectively.

According to the present specification, cracks can be prevented or reduced from occurring in a cathode electrode. Accordingly, since an increase in resistance of the cathode electrode is improved, low power driving can be performed.

Effects of the present specification are not limited to the above-mentioned effects, and other effects which are not mentioned will be clearly understood by those skilled in the art from the description of the claims.

Since the contents of the specification described in the problem to be solved, the means to solve the problem, and the effects described above do not specify the essential features of the claims, the scope of the claims is not limited by the items described in the contents of the specification.

Although the embodiments have been described in more detail with reference to the accompanying drawings, the present disclosure is not necessarily limited to these embodiments, and may be variously modified without departing from the technical concepts of the present disclosure. Accordingly, the embodiments disclosed in the present disclosure are not intended to limit the technical concepts of the present disclosure, but to describe the technical concepts of the present disclosure, and the scope of the technical concepts of the present disclosure is not limited by these embodiments. Accordingly, the above-described embodiments should be understood in all respects as illustrative and not restrictive.

What is claimed is:

1. A display device comprising:
a substrate;
a plurality of first electrodes on the substrate;
a contact electrode on the substrate;
a plurality of light-emitting elements on the plurality of first electrodes;
a first optical layer between the plurality of light-emitting elements; and
a second electrode on the plurality of light-emitting elements, the second electrode including a first region that is on the plurality of light-emitting elements and a second region that extends an outside of the first optical layer and is in contact with the contact electrode.

2. The display device of claim 1, further comprising:
a second optical layer that covers the second region of the second electrode.

3. The display device of claim 2, wherein the first optical layer includes a first material and the second optical layer includes a second material that is different from the first material.

4. The display device of claim 3, wherein the first optical layer includes light scattering particles.

5. The display device of claim 1, further comprising:
a plurality of bank patterns between the substrate and the plurality of first electrodes, the plurality of first electrodes on an upper surface of the plurality of bank patterns.

6. The display device of claim 5, further comprising:
a plurality of signal lines extending between the plurality of bank patterns, the plurality of signal lines connected to the plurality of first electrodes.

7. The display device of claim 6, wherein the contact electrode is between the plurality of signal lines.

8. The display device of claim 2, further comprising:
a plurality of second electrodes including the second electrode, the plurality of second electrodes arranged across a plurality of pixel rows and each of the plurality of second electrodes is spaced apart from each other for each pixel row from the plurality of pixel rows,
wherein the plurality of second electrodes are electrically connected to the contact electrode.

9. The display device of claim 1, wherein the second electrode includes a third region on a side surface of the first optical layer, the third region connecting the first region and the second region.

10. The display device of claim 1, further comprising:
an insulating layer on the substrate;
a plurality of connection lines between the substrate and the insulating layer; and
a pixel driving circuit connected to the plurality of connection lines,
wherein the plurality of connection lines are electrically connected to the plurality of first electrodes and the contact electrode.

11. The display device of claim 1, wherein the plurality of light-emitting elements are inorganic light-emitting diodes.

12. The display device of claim 10, wherein the pixel driving circuit is a driving circuit.

13. A display device comprising:
a substrate;
a plurality of first electrodes on the substrate;
a plurality of light-emitting elements on the plurality of first electrodes;
a first optical layer between the plurality of light-emitting elements;
a second electrode on the plurality of light-emitting elements, the second electrode including a first region that is on the plurality of light-emitting elements and a second region extends an outside of the first optical layer; and
a second optical layer surrounding the first optical layer, the second optical layer on the second region of the second electrode.

14. The display device of claim 13, wherein the first optical layer includes a first material and the second optical layer includes a second material that is different from the first material.

15. The display device of claim 14, wherein the first optical layer includes light scattering particles.

16. The display device of claim 13, further comprising:
a plurality of bank patterns between the substrate and the plurality of first electrodes, the plurality of first electrodes on an upper surface of the plurality of bank patterns.

17. The display device of claim 16, further comprising:
a plurality of signal lines extending between the plurality of bank patterns, the plurality of signal lines connected to the plurality of first electrodes.

18. The display device of claim 17, further comprising:
a contact electrode on the substrate and between the plurality of signal lines, the contact electrode connected to the second electrode.

19. The display device of claim 18, further comprising:
a plurality of second electrodes including the second electrode, the plurality of second electrodes arranged across a plurality of pixel rows and each of the plurality of second electrodes is spaced apart from each other for each pixel row from the plurality of pixel rows,
wherein the plurality of second electrodes are electrically connected to the contact electrode.

20. The display device of claim 18, further comprising:
an insulating layer on the substrate;
a plurality of connection lines between the substrate and the insulating layer; and
a pixel driving circuit connected to the plurality of connection lines,
wherein the plurality of connection lines are electrically connected to the plurality of first electrodes and the contact electrode.
